(19) United States
(12) Patent Application Publication
(10) Pub. No.: US 2006/0148176 A1
(43) Pub. Date: Jul. 6, 2006

(54) Method of manufacturing a gate in a flash memory device

(75) Inventors: Dong-Oog Kim, Seoul (KR); Chang-Hun Han, Icheon-city (KR)

Correspondence Address: OBLON, SPIVAK, MCCLELLAND, MAIER & NEUSTADT, P.C., 1940 DUKE STREET, ALEXANDRIA, VA, 22314, US

(73) Assignee: DongbuAnam Semiconductor Inc., Seoul (KR)

(21) Appl. No.: 11/320,687

(22) Filed: Dec. 30, 2005

(30) Foreign Application Priority Data
Dec. 30, 2004 (KR) 10-2004-0117161

(51) Int. Cl. H01L 21/336

(52) U.S. Cl. 438/264; 438/261; 438/257

(57) ABSTRACT

A method of manufacturing a gate in a flash memory device. The method includes forming a stacking structure including a tunnel oxide layer, a floating gate, a dielectric layer, and a control gate on a semiconductor substrate. The further includes removing a remaining portion of the tunnel oxide layer exposed by the control gate by wet etching to a degree that the semiconductor substrate is exposed, and forming an oxide layer covering the exposed portion of the semiconductor substrate and both sidewalls of the floating gate and the control gate.

### CROSS-REFERENCE TO RELATED APPLICATION

This application claims priority to and the benefit of Korean Patent Application No. 10-2004-0117161 filed in the Korean Intellectual Property Office on Dec. 30, 2004, the entire contents of which are incorporated herein by reference.

### BACKGROUND OF THE INVENTION

(a) Field of the Invention

The present invention relates to a method of manufacturing a semiconductor device, and more particularly relates to a method of manufacturing a gate in a flash memory device having advantages of reducing an off-current (I_{off}) in a flash cell.

(b) Description of the Related Art

A flash memory device is a non-volatile memory device having a floating gate and a control gate in its stacking structure. In the case of an EEPROM device, a stacking structure including a floating gate and control gate is formed in its dual conductive polysilicon structure. The stacking structure is formed on a tunnel oxide layer

An ONO (Oxide-Nitride-Oxide) layer used as a dielectric layer is formed between a floating gate and a control gate. The ONO layer performs a function of a capacitor.

A bias applied at a control gate can be applied at a floating gate through an ONO layer. Program and erase operations for a flash memory are performed by using a relatively high bias.

FIG. 1 is a top plan view briefly showing a layout of a flash memory device manufactured by a conventional method.

Referring to FIG. 1, a flash memory device generally includes 512 word lines 11 and 1024 bit lines 13. A single cell 17 is set on a crossing point of a word line 11 and a bit line 13, and the bit line is electrically connected to the cell 17 through a bit line contact 15. As shown in FIG. 1, since the single word line 11 passes through the 1024 bit lines 13, an effective reduction of current leakage is important for ensuring characteristics of a flash memory device.

However, current leakage points may occur during an etching process for a control gate of a flash memory device, and the current leakage points are relatively weak during the subsequent process for forming lateral sides of an oxide layer because they are damaged by plasma used in etching a control gate.

FIG. 2 and FIG. 3 are cross-sectional views showing a conventional method of manufacturing a gate in a flash memory device.

Referring to FIG. 2, a tunnel oxide 23 is formed on a semiconductor substrate 21, and then a floating gate 25 is formed on the tunnel oxide 23. Subsequently, an ONO layer 27 as a dielectric layer is formed on the floating gate 25, and then a control gate 28 is formed on the ONO layer 27. As shown in FIG. 2, when the control gate 28 is patterned so as to have an extended pattern like the word line 13, the dielectric layer 27 and the floating gate 25 are self-aligned.

During an etching process for the control gate 28, a portion 24 of the tunnel oxide 23 exposed by the control gate 28 can be damaged by plasma used for etching the control gate 28.

Referring to FIG. 3, after patterning the control gate 28, an oxide layer 29 is formed at both sidewalls of the gates 25 and 28 by oxidizing both sidewalls thereof. However, when the oxide layer 29 is formed, a weak portion 26 may be created due to the part 24 damaged by plasma, and current leakage may occur at the weak portion 26.

Therefore, a method for preventing an occurrence of the weak portion 26 is required for manufacturing a gate in a flash memory device.

The above information disclosed in this Background section is only for enhancement of understanding of the background of the invention and therefore it may contain information that does not form part of the prior art with respect to the present invention.

### SUMMARY OF THE INVENTION

The present invention has been made in an effort to provide a method of manufacturing a gate in a flash memory device having advantages of preventing current leakage caused by plasma used for etching a control gate.

An exemplary method of manufacturing a gate in a flash memory device according to an embodiment of the present invention includes: forming a stacking structure including a tunnel oxide layer, a floating gate, a dielectric layer, and a control gate on a semiconductor substrate; removing a remaining portion of the tunnel oxide layer exposed by the control gate by wet etching to a degree that the semiconductor substrate is exposed; and forming an oxide layer covering the exposed portion of the semiconductor substrate and both sidewalls of the floating gate and the control gate.

Before forming the tunnel oxide layer on the semiconductor substrate, the method further includes: sequentially depositing an oxide layer, a nitride layer, and a TEOS layer on the semiconductor substrate; forming a trench by etching the oxide layer, the nitride layer, the TEOS layer, and a predetermined depth of the semiconductor substrate with the use of a mask defining active regions on the TEOS layer; and performing a planarization process for a fill insulation layer filling in the trench.

The fill insulation layer can be composed of HDP-USG (High Density Plasma-Undoped Silicate Glass).

The dielectric layer can be an ONO (Oxide-Nitride-Oxide) layer.

The wet etching can be performed by using an etchant including diluted hydrofluoric acid (DHF).

The oxide layer covering both sidewalls of the gates can be formed by performing a rapid thermal annealing (RTA) process.

The rapid thermal annealing (RTA) process can be performed at a temperature of 1050° C., and the oxide layer covering both sidewalls of the gates can be formed to a uniform thickness of about 60 Å.

The control gate can be formed as a control gate of a NOR flash memory cell.

Therefore, according to an exemplary embodiment of the present invention, a method of manufacturing a gate in a flash memory device having advantages of preventing current leakage caused by plasma used for etching a control gate can be provided.

### BRIEF DESCRIPTION OF THE DRAWINGS

FIG. 1 is a top plan view briefly showing a layout of a flash memory device manufactured by a conventional method.

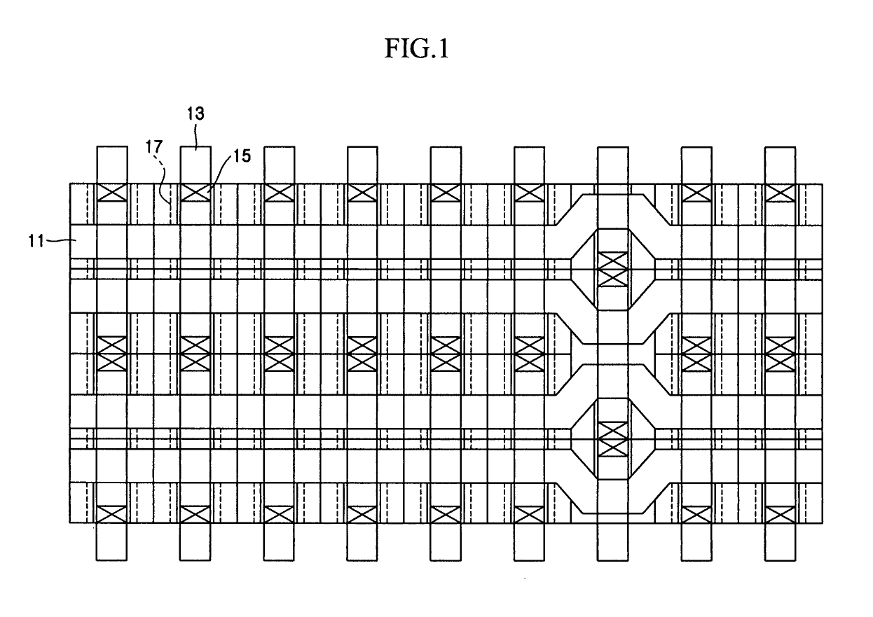

FIG. 2 and FIG. 3 are cross-sectional views showing a conventional method of manufacturing a gate in a flash memory device.

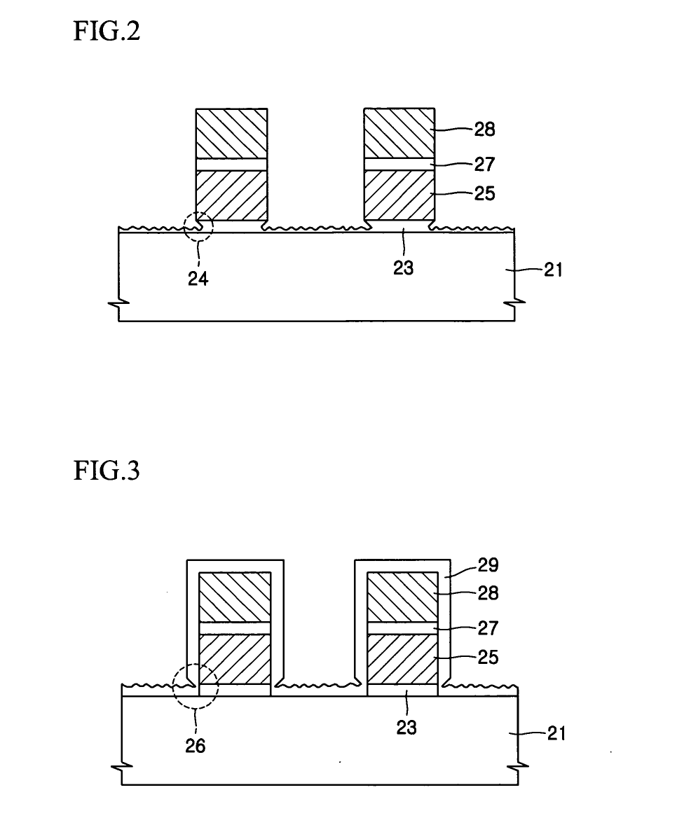

FIG. 4 and FIG. 5 are cross-sectional views showing a method of manufacturing a gate in a flash memory device according to an exemplary embodiment of the present invention.

### DETAILED DESCRIPTION OF THE EMBODIMENTS

With reference to the accompanying drawings, the present invention will be described in order for those skilled in the art to be able to implement the invention. As those skilled in the art would realize, the described embodiments may be modified in various different ways, all without departing from the spirit or scope of the present invention.

To clarify multiple layers and regions, the thicknesses of the layers are enlarged in the drawings. Like reference numerals designate like elements throughout the specification. When it is said that any part, such as a layer, film, area, or plate is positioned on another part, it means the part is directly on the other part or above the other part with at least one intermediate part. On the other hand, if any part is said to be positioned directly on another part it means that there is no intermediate part between the two parts.

According to an exemplary embodiment of the present invention, an oxide residue, such as a residue of a tunnel oxide layer that remains after an etching process for a control gate, is removed, and then a new oxide layer is grown. Accordingly, the operation characteristics of a NOR flash memory device, such as an ETOX (EEPROM Tunnel Oxide) memory cell, can be enhanced. Consequently, an off-current (I_{off}) of a flash cell can be reduced and over-erase can be prevented. In addition, the retention characteristic of an ETOX (EEPROM Tunnel Oxide) memory cell can be enhanced.

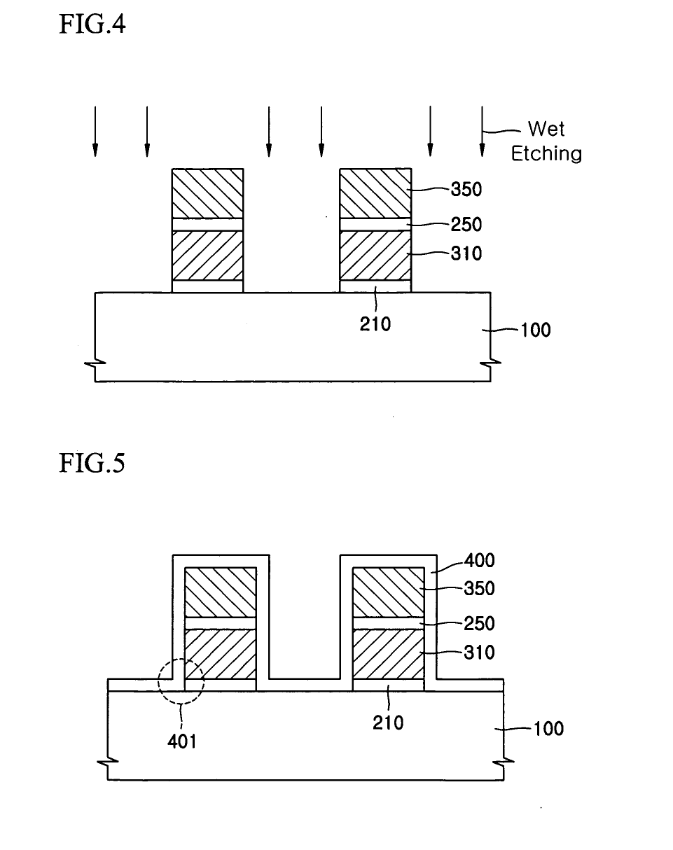

FIG. 4 and FIG. 5 are cross-sectional views showing a method of manufacturing a gate in a flash memory device according to an exemplary embodiment of the present invention.

Referring to FIG. 4, an oxide layer, a nitride layer, and a TEOS layer are sequentially deposited on a semiconductor substrate 100, such as a silicon wafer, and then they are etched after forming a mask which distinguishes active regions from field regions. Subsequently, an STI (Shallow Trench Isolation) region is formed by performing an oxidation process for a buffer layer, and by performing a filling process with the use of HDP-USG (High Density Plasma-Undoped Silicate Glass). Thereafter, a planarization process is performed, and then a well and a junction are formed.

Subsequently, a tunnel oxide layer 210 and a floating gate layer 310 are formed on the semiconductor substrate 100, and then they are etched by using a mask. An ONO layer 250 used as a dielectric layer is deposited on the floating gate layer 310, and a control gate layer 350 is formed on the ONO layer. At this time, before forming the control gate layer 350, the ONO layer 250, the floating gate layer 310, and the tunnel oxide layer 210 which are formed in the region other than a flash cell are selectively removed by etching with the use of a mask.

Subsequently, the control gate layer 350 is patterned by etching with the use of the mask. As shown in FIG. 4, a stacking structure including the tunnel oxide layer 210, the floating gate layer 310, the dielectric layer 250, and the control gate layer 350 is formed by the above-mentioned patterning processes.

After forming the control gates 350, polymers created in the etching process are removed by performing cleaning and ashing processes.

As shown in FIG. 4, a surface of the semiconductor substrate 100 between control gates 350 is exposed by selectively removing a remaining portion of the tunnel oxide layer 210 exposed by the control gates 350.

The etching process for the remaining portion of the tunnel oxide layer 210 exposed by the control gates 350 is performed by using wet etching. An etchant including diluted Hydrofluoric acid (DHF) is used for the wet etching.

Subsequently, additional gates for logic circuits are formed in peripheral circuit regions by using masks and etching processes for logic gates. Thereafter, a cell common source is formed by using a mask for an SAS (Self Aligned Source).

Referring to FIG. 5, an oxide layer 400 covering the exposed portion of the semiconductor substrate 100 and both sidewalls of the gates 310 and 350 is finally formed to a thickness of about 60 Å by performing a RTA (Rapid Thermal Annealing) process at a temperature of about 1050° C. Since the oxide layer 400 is actually a pure oxide layer which is a new oxide layer formed after removing the part damaged by plasma, it can be uniformly grown. Therefore, unlike the conventional method by which weak portions are created, the oxide layer 400 can be grown in a uniform thickness even at a portion 401 at the edge of the floating gate 310. Consequently, current leakage can be effectively prevented.

According to an exemplary embodiment of the present invention, since a remaining tunnel oxide layer exposed by a gate is removed and then a new oxide layer is grown, an off-current (I_{off}) in a flash cell can be reduced and over erase can be prevented. In addition, the retention characteristic of an ETOX (EEPROM Tunnel Oxide) memory cell can be enhanced.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A method of manufacturing a gate in a flash memory device, comprising:
forming a stacking structure including a tunnel oxide layer, a floating gate, a dielectric layer, and a control gate on a semiconductor substrate;
removing a remaining portion of the tunnel oxide layer exposed by the control gate by wet etching to a degree that the semiconductor substrate is exposed; and
forming an oxide layer covering the exposed portion of the semiconductor substrate and both sidewalls of the floating gate and control gate.

2. The method of claim 1, further comprising:
sequentially depositing an oxide layer, a nitride layer, and a TEOS layer on the semiconductor substrate before forming the tunnel oxide layer on the semiconductor substrate;
forming a trench by etching the oxide layer, the nitride layer, the TEOS layer, and a predetermined depth of the semiconductor substrate using a mask defining active regions on the TEOS layer; and
performing a planarization process for a fill insulation layer filling in the trench.

3. The method of claim 2, wherein the fill insulation layer is composed of HDP-USG (High Density Plasma-Undoped Silicate Glass).

4. The method of claim 1, wherein the dielectric layer is an ONO (Oxide-Nitride-Oxide) layer.

5. The method of claim 1, wherein the wet etching is performed by using an etchant including diluted hydrofluoric acid (DHF).

6. The method of claim 1, wherein the oxide layer covering both sidewalls of the gates is formed by performing a rapid thermal annealing (RTA) process.

7. The method of claim 6, wherein the rapid thermal annealing (RTA) process is performed at a temperature of 1050° C.

8. The method of claim 6, wherein the oxide layer covering both sidewalls of the gates is formed to a uniform thickness of about 60 Å.

9. The method of claim 1, wherein the control gate is formed as a control gate of a NOR flash memory cell.
